(19) United States
(12) Patent Application Publication
(10) Pub. No.: US 2019/0129479 A1
(43) Pub. Date: May 2, 2019

(54) WATER COOLING PLATE COMPOSED OF MULTI CHANNELS

(71) Applicant: Zheming Zhou, Guangzhou, Guangdong (CN)

(72) Inventor: Zheming Zhou, Guangzhou, Guangdong (CN)

(21) Appl. No.: 16/093,703

(22) PCT Filed: Apr. 12, 2017
(86) PCT No.: PCT/CN2017/080291

§ 371 Date: Oct. 15, 2018

(30) Foreign Application Priority Data
Apr. 15, 2016 (CN) 201610233778.6

(51) Int. Cl. G06F 1/20; H05K 7/20

(52) U.S. Cl. CPC G06F 1/20; G06F 2200/201; H05K 7/20254; H05K 7/20272

(57) ABSTRACT

Disclosed is a water cooling plate composed of multi channels, comprising a plate body (1), a water chamber (2), and a waterproof baffle (3), wherein the plate body (1) is composed of at least two pipelines (4), the pipelines (4) being bent according to the shape of a flow channel one by one and being combined in parallel to form the plate body (1); the plate body (1) can be mounted on a baseplate; the water chamber (2) is provided with a water pipe joint (9); the waterproof baffle (3) being provided between the water chamber (2) and the plate body (1); the pipelines (4) penetrate the waterproof baffle (3), and flow directions of adjacent pipelines (4) can be provided in opposite directions. The structure is flexible in flow channel distribution, and has high heat dissipation efficiency.

### TECHNICAL FIELD

The present disclosure relates to electronic devices, and more particularly to the dissipation of heat generated by high power electronic devices such as power batteries, servers, network devices, and the like.

### BACKGROUND OF THE INVENTION

Water cooling technology, a kind of efficient heat dissipation scheme, has been widely used in electronic devices. In a heat dissipation system adopting water cooling technology, a water cooling plate which is a key and core component of the heat dissipation system adopting water cooling technology is an important part. The design and manufacture of a water cooling plate determines critical technical indicators of a heat dissipation system, such as heat dissipation efficiency and reliability.

The applicant has proposed a water cooling plate based on a porous flat tube in a Chinese patent application No. 201320136068.3. A porous flat tube section is used as a substrate in the water cooling plate, the porous flat tube is trepanned on its wall as an inlet and an outlet, and the water tube joint is welded. The water cooling plate based on the porous flat tube is simple to process, the welding surface is small, the plate body is light and the water channel is large; however, the disadvantaged thereof is that the width of the water cooling plate is limited by the width of the porous flat pipe section. If the porous flat tube can be bent horizontally, the width of the water cooling plate based on the porous flat tube can be doubled, which may break through the limitation of the porous flat tube section. Moreover, such bending water-cooled plate may have the advantage of less weld seam compared with the applicant's another Chinese patent application No. 201410053542.5. However, it is difficult to bend the porous flat tube horizontally. The wider the porous flat tube, the smaller the bending radius, while the greater the difference between the inner and outer arc lengths after bending, the easier it is to break through the limits of stretching and compression of the material.

### SUMMARY OF THE INVENTION

In order to obtain a water cooling plate having the above-mentioned excellent characteristics, the present disclosure provides a water cooling plate composed of multi channels, which is formed by bending a plurality of pipelines one by one and then placing side by side, similar to the appearance of a water cooling plate based on a porous flat tube after horizontal bended.

The technical solution adopted by the present disclosure to solve the technical problem thereof is:

A water cooling plate composed of multi channels may include a plate body, a water chamber and a waterproof baffle. The plate body is composed of at least two pipelines which are round pipelines, square pipelines or flat pipelines and have single hole or multiple holes, generally the pipelines may be round pipelines with single hole. The pipelines may be bent one by one according to the shape of a flow channel and then be combined in parallel to form the plate body. The plate body may be mounted on a baseplate which is a plat plate or a plat plate having a pipeline groove. The plate body may be processed with leveling as needed. The water chamber may be composed of a water chamber bottom plate and a water chamber cover sheet, and a water pipe joint is arranged on the water chamber bottom plate or the water chamber cover sheet. A waterproof baffle is provided between the plate body and a water chamber, and the pipelines pass through the waterproof baffle. A connection way of the flow channel is to divide the water chamber into several small water chambers with a water chamber baffle, and both ends of the pipelines pass through the water chamber bottom plate and connect each of the small water chambers and the water pipe joint to form the flow channel. While another connection way of the flow channel is to use a plurality of water chambers, and both ends of the pipeline pass through the water chamber bottom plate and connect each of the water chambers and the water pipe joint to form the flow channel. The flow directions of the pipelines of the plate body are in opposite directions to achieve thermal balance.

The present disclosure has the beneficial effects that, by bending the pipelines one by one according to the shape of the flow channel and then combining them in parallel to form the water cooling plate, the structure is flexible in flow channel distribution, easy to process, and has a light and thin plate body; by making the welding beads at the water chamber, the welding face is small, improving the reliability; by making no welding beads at a contacting portion between the water cooling plate and the electronic device, and by isolating the water chamber from the plate body with the waterproof baffle, leakage cooling water can be blocked from flowing to the electronic device, enhancing the safety; by connecting the water chambers or small water chambers with the pipelines to form the flow channel, the combination of the flow channel is flexible, implementing a good thermal balancing, and the flow rate and flow resistance can be adjustable, rising the heat dissipation efficiency; and by providing flow directions of adjacent pipelines in opposite directions, achieving thermal balance.

### BRIEF DESCRIPTION OF THE DRAWINGS

FIG. 1 is a perspective view of a water cooling plate in accordance with the present disclosure.

FIG. 2 is a schematic view showing the structure of a water chamber of a water cooling plate in accordance with the present disclosure.

FIG. 3 is a schematic plane view showing the structure of a water cooling plate in accordance with the present disclosure.

In the figures,
1. plate body,
2. water chamber,
3. waterproof baffle,
4. pipelines,
5. water chamber bottom plate,
6. water chamber cover sheet,
7. water chamber baffle,
8. small water chamber,
9. water pipe joint.

### DETAILED DESCRIPTION

The present disclosure will be further described below in conjunction with the accompanying drawings and embodiments.

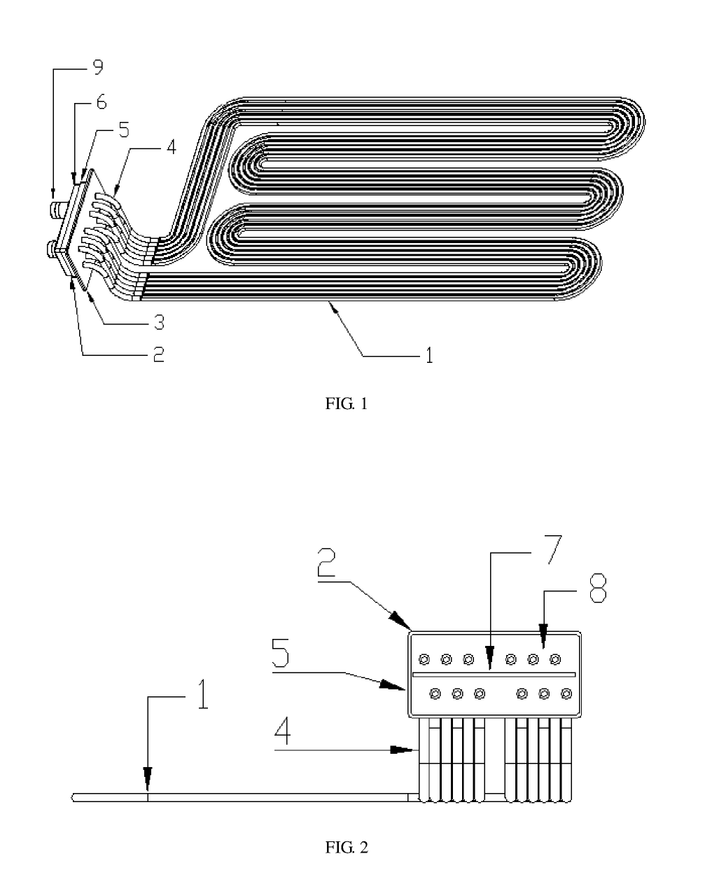

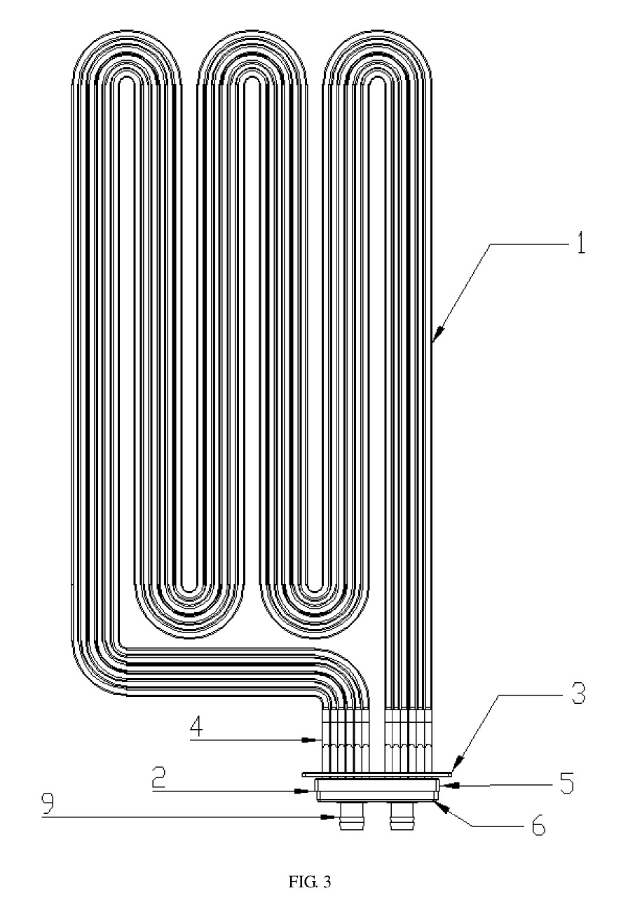

As shown in FIGS. 1, 2, and 3, a water cooling plate composed of multi channels may include a plate body 1, a water chamber 2 and a waterproof baffle 3. The plate body 1 is composed of at least two pipelines 4. The pipelines 4 may be round pipelines with single hole. The pipelines 4 may be bent one by one according to the shape of a flow channel and then be combined in parallel to form the plate body 1. The plate body 1 may be processed with leveling. The water chamber 2 may be composed of a water chamber bottom plate 5 and a water chamber cover sheet 6, and a water pipe joint 8 is arranged on the water chamber cover sheet 6. A waterproof baffle 3 is provided between the plate body land the water chamber 2, and the pipelines 4 pass through the waterproof baffle 3. A connection way of the flow channel is to divide the water chamber 2 into several small water chambers 8 with a water chamber baffle 7, and both ends of the pipelines 4 pass through the water chamber bottom plate 5 and connect each of the small water chambers 8 and the water pipe joint 9 to form the flow channel. The flow directions of adjacent pipelines 4 are in opposite directions to achieve thermal balance.

1. A water cooling plate composed of multi channels, comprising: a plate body, wherein the plate body is composed of at least two pipelines, the pipelines being bent one by one according to the shape of a flow channel and then being combined in parallel to form the plate body.

2. The water cooling plate according to claim 1, wherein a waterproof baffle is provided between the plate body and a water chamber, and the pipelines pass through the waterproof baffle.

3. The water cooling plate according to claim 1, wherein the water chamber is composed of a water chamber bottom plate and a water chamber cover sheet, and a water pipe joint is arranged on the water chamber; the connection way of the flow channel is to divide the water chamber into several small water chambers with a water chamber baffle, and both ends of the pipeline pass through the water chamber bottom plate and connect each of the small water chambers and the water pipe joint to form the flow channel.

4. The water cooling plate according to claim 1, wherein the water chamber is composed of a water chamber bottom plate and a water chamber cover sheet, and a water pipe joint is arranged on the water chamber; the connection way of the flow channel is to use a plurality of water chambers, and both ends of the pipeline pass through the water chamber bottom plate and connect each of the water chambers and the water pipe joint to form the flow channel.

5. The water cooling plate according to claim 1, wherein the plate body is mounted on a baseplate which is a plat plate.

6. The water cooling plate according to claim 1, wherein the plate body is mounted on a baseplate which is a plat plate with a pipeline groove.

7. The water cooling plate according to claim 1, wherein the flow directions of the pipelines of the plate body are in opposite directions to achieve thermal balance.

8. The water cooling plate according to claim 2, wherein the water chamber is composed of a water chamber bottom plate and a water chamber cover sheet, and a water pipe joint is arranged on the water chamber; the connection way of the flow channel is to divide the water chamber into several small water chambers with a water chamber baffle, and both ends of the pipeline pass through the water chamber bottom plate and connect each of the small water chambers and the water pipe joint to form the flow channel.

9. The water cooling plate according to claim 2, wherein the water chamber is composed of a water chamber bottom plate and a water chamber cover sheet, and a water pipe joint is arranged on the water chamber; the connection way of the flow channel is to use a plurality of water chambers, and both ends of the pipeline pass through the water chamber bottom plate and connect each of the water chambers and the water pipe joint to form the flow channel.

10. The water cooling plate according to claim 2, wherein the plate body is mounted on a baseplate which is a plat plate.

11. The water cooling plate according to claim 2, wherein the plate body is mounted on a baseplate which is a plat plate with a pipeline groove.

12. The water cooling plate according to claim 2, wherein the flow directions of the pipelines of the plate body are in opposite directions to achieve thermal balance.
